(19) United States
(12) Patent Application Publication
(10) Pub. No.: US 2008/0036077 A1
(43) Pub. Date: Feb. 14, 2008

(54) Package structure and heat sink module thereof

(75) Inventor: Sung-Fei Wang, Kaohsiung (TW)

Correspondence Address: BIRCH STEWART KOLASCH & BIRCH, PO BOX 747, FALLS CHURCH, VA, 22040-0747, US

(73) Assignee: Advanced Semiconductor Engineering, Inc.

(21) Appl. No.: 11/642,552

(22) Filed: Dec. 21, 2006

(30) Foreign Application Priority Data
Aug. 14, 2006 (TW) 95129813

(51) Int. Cl. H01L 23/34

(52) U.S. Cl. 257/717

(57) ABSTRACT

A package structure and a heat sink module thereof are provided. The package structure includes a substrate, a chip and a heat sink module. The chip is disposed on the substrate. The heat sink module includes a supporting ring and a heat sink plate. The supporting ring is disposed on the substrate and surrounds the chip. Four recesses are formed on an upper surface of the supporting ring. The heat sink plate is disposed on the chip and includes four protruding parts lodged in the recesses.

This application claims the benefit of Taiwan application Serial No. 095129813, filed Aug. 14, 2006, the subject matter of which is incorporated herein by reference.

### BACKGROUND OF THE INVENTION

1. Field of the Invention

The invention relates in general to a package structure and a heat sink module thereof, and more particularly to a package structure and a heat sink module thereof with a heat sink plate lodged in a supporting ring.

2. Description of the Related Art

As semiconductor packaging technology develops rapidly, all kinds of chips are packaged to protect the chips from moisture and electrically connect inner circuits of the chips with wires of printed circuit boards. However, heat generated by the chips needs to be dissipated to protect the inner circuits, so that the efficiency of the chips is not affected. A conventional package structure is illustrated as follow.

FIG. 1 illustrates an exploded view of a conventional package structure. Please referring to FIG. 1, a conventional package structure 100 includes a substrate 110, a chip 120, a supporting ring 130 and a heat sink plate 140. The chip 120 is disposed on the substrate 110. The supporting ring 130 is disposed on the substrate 110 and surrounds the chip 120 for supporting the heat sink plate 140. The heat sink plate 140 is disposed on the chip 120 and the supporting ring 130. A thermal adhesive 160 is used for adhering the supporting ring 130 and the substrate 110, the supporting ring 130 and the heat sink plate 140, and the heat sink plate 140 and the chip 120.

Please referring to FIG. 2, an assembled view of the package structure in FIG. 1 is illustrated in FIG. 2. When the heat sink plate 140 and the supporting ring 130 are adhered to the substrate 110, the supporting ring 130 supports the heat sink plate 140. As a result, the heat sink plate 140 is attached to the chip 120 for dissipating heat generated by the chip 120. However, because the thermal adhesive 160 is a gel, relative displacement easily occurs between the heat sink plate 140 and the supporting ring 130.

Please referring to FIG. 3, FIG. 3 illustrates another assembled view of the package structure in FIG. 1. Because the substrate 140 is not rigid, four corners of the package structure 100 are warped easily, especially in a large-size substrate. The thickness of the supporting ring 130 is substantially the same as that of the chip 120, so that the heat sink plate 140 is contact on the surface of the chip 120. Therefore, the conventional supporting ring 130 is not thick enough to overcome the warping stress. However, if the supporting ring 130 is thicker than the chip 120, the heat sink plate 140 is not able to contact the chip 120 to dissipate heat. Thus, in the conventional package structure 100, tin balls 150 are not disposed at the corners of the substrate 110 as I/O pins, so that the package structure 100 functions well even when the package structure 100 is warped.

As stated above, the heat sink plate 140 is easily displaced in the conventional package structure and the substrate 110 is easily warped. The defective rate and cost of the manufacturing process can not be decrease. Therefore, it is really important to prevent the heat sink plate 140 from displacing and the substrate 110 from warping.

### SUMMARY OF THE INVENTION

It is therefore an object of the invention to provide a package structure and a heat sink module thereof. A heat sink plate and a supporting ring include protruding parts and recesses respectively, so that the heat sink plate is lodged in the supporting ring. The thickness of corners of the supporting ring is enough to prevent the substrate from warping. As a result, tin balls are able to be disposed at the corners of the substrate. Furthermore, the supporting ring effectively prevents the heat sink plate from displacing because the heat sink plate is placed against inner walls of the supporting ring. Therefore, the heat sink module dissipates heat of the chip and prevents the substrate from warping and the heat sink plate from displacing. The efficiency of the manufacturing process and the quality of the package structure are increased greatly.

The invention achieves the above-identified object by providing a package structure. The package structure includes a substrate, a chip, a supporting ring and a heat sink plate. The chip is disposed on the substrate. The supporting ring is disposed on the substrate and surrounds the chip. Four recesses are formed on an upper surface of the supporting ring. The heat sink plate is disposed on the chip and includes four protruding parts lodged in the recesses.

The invention achieves the above-identified object by providing a heat sink module disposed in a package structure. The package structure includes a substrate and a chip. The chip is disposed on the substrate. The heat sink module includes a supporting ring and a heat sink plate. The supporting ring is disposed on the substrate and surrounds the chip. Four recesses are formed on an upper surface of the supporting ring. The heat sink plate is disposed on the chip and includes four protruding parts lodged in the recesses.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1 (Prior Art) illustrates an exploded view of a conventional package structure;

FIG. 2 (Prior Art) illustrates an assembled view of the package structure in FIG. 1;

FIG. 3 (Prior Art) illustrates another assembled view of the package structure in FIG. 1;

FIG. 4 illustrates an exploded view of a package structure according to a preferred embodiment of the invention;

FIG. 5 illustrates the package structure in FIG. 4 when a supporting ring is adhered to a substrate; and

FIG. 6 illustrates the package structure in FIG. 5 when a heat sink plate is adhered to the supporting ring and a chip.

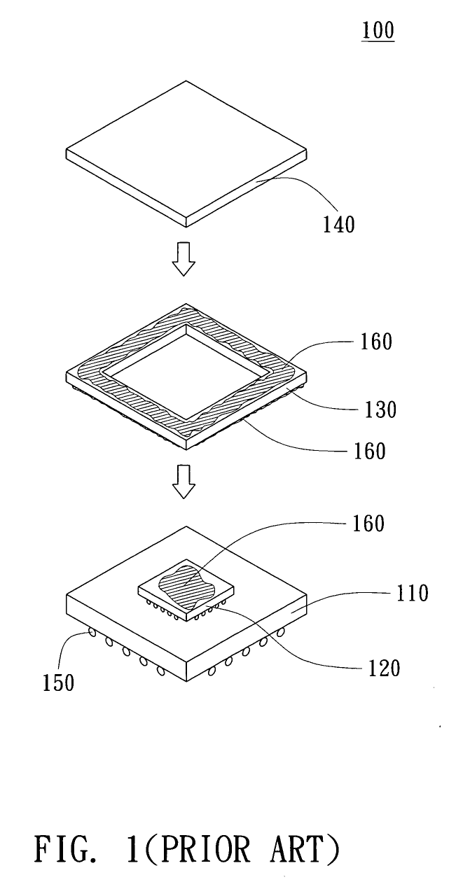

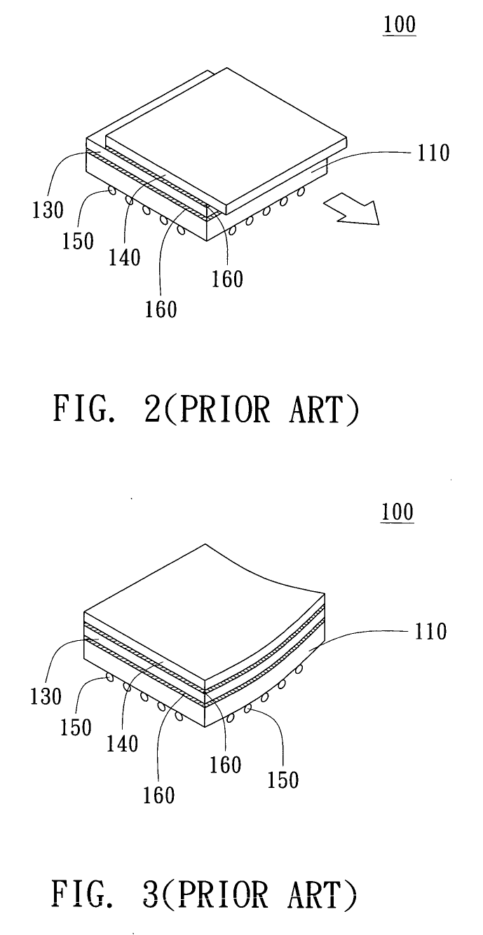

### DETAILED DESCRIPTION OF THE INVENTION

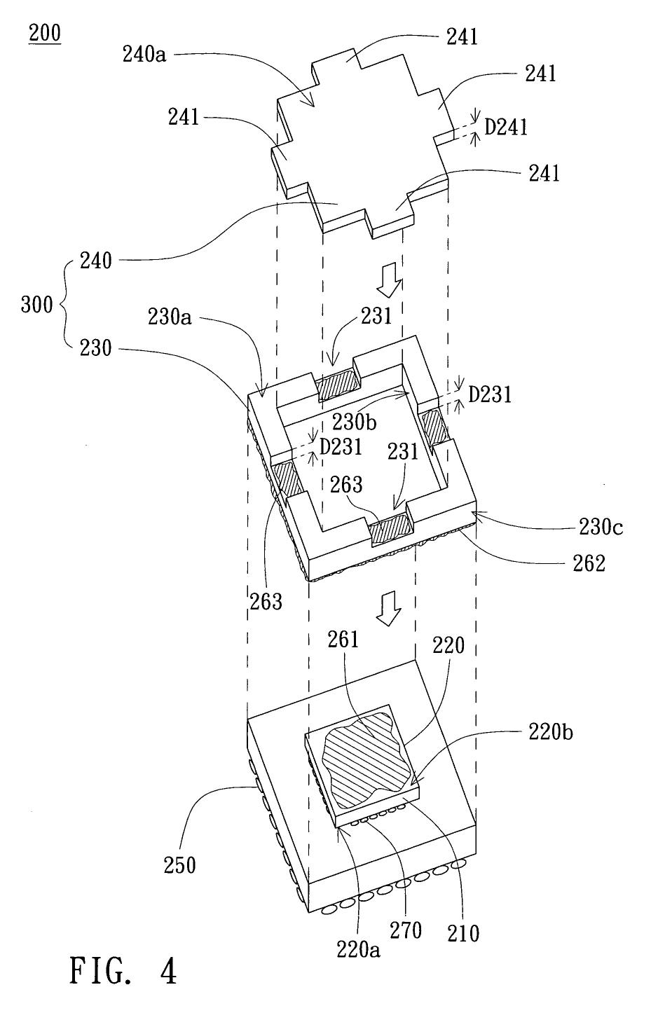

Please referring to FIG. 4, FIG. 4 illustrates an exploded view of a package structure according to a preferred embodiment of the invention. A package structure 200 includes a substrate 210, a chip 220 and a heat sink module 300. The chip 220 is disposed on the substrate 210. The heat sink module 300 includes a supporting ring 230 and a heat sink plate 240. At least one recess 231 (preferably, the embodiment of the present invention is four recesses) is formed on an upper surface 230a of the supporting ring 230. The heat sink plate 240 including at least one protruding part 214 (preferably, the embodiment of the present invention is four protruding parts) is disposed on the chip 220. The protruding parts 241 are disposed correspondingly to the recesses 231, so that the protruding parts 241 of the heat sink plate 240 are lodged in the recesses 231 of the supporting ring 230.

In the present embodiment, the package structure is a flip-chip ball grid array (FC BGA) package structure as an example. The package structure 200 further includes several bumps 270 disposed on an active surface 220a of the chip 220. The bumps 270 are connected to the substrate 210 physically, such as alloying connection, and electrically.

As shown in FIG. 4, the supporting ring 230 is an annular rectangular structure. The supporting ring 230 is formed by four cuboids surrounding the chip 220. The recesses 231 are disposed on four sides of the supporting ring 230 evenly. However, the shape and the position of the recesses 231 are not limited thereto. Anyone who has ordinary skill of the invention can make modifications. In the present embodiment, the recesses 231 penetrate the inner walls 230b and the outer walls 230c of the supporting ring 230. However, the invention is not limited thereto. As long as the heat sink plate 240 and the supporting ring 230 are lodged in each other through the protruding parts and the recesses, the invention encompasses all such modifications.

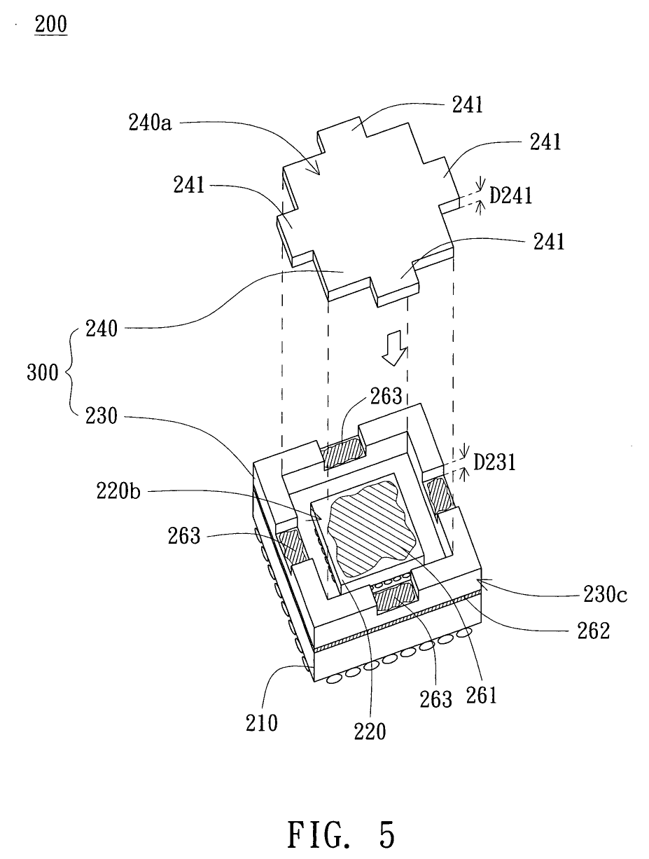

Please referring to FIG. 5, FIG. 5 illustrates the package structure in FIG. 4 when the supporting ring is adhered to the substrate. The package structure 200 further includes a first thermal adhesive 261 disposed on a non-active surface 220b of the chip 220. The first thermal adhesive 261 is used for adhering the heat sink plate 240 and the chip 230.

Preferably, the supporting ring 230 and the heat sink plate 240 are made of thermal conductive material, such as metal, ceramic material or polymers. Additionally, the package structure 200 further includes a second thermal adhesive 262 and a third thermal adhesive 263. The second thermal adhesive 262 is disposed between the supporting ring 230 and the substrate 210 for adhering the supporting ring 230 and the substrate 210. The third thermal adhesive 263 is disposed on the bottom of the recesses 231 for adhering the supporting ring 230 and the heat sink plate 240.

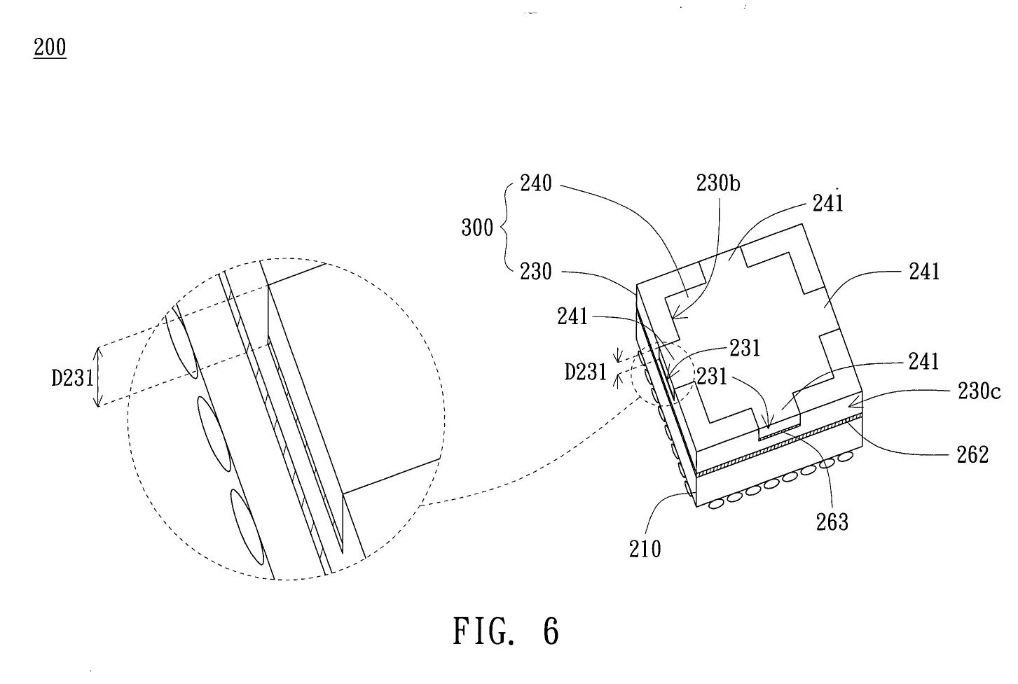

FIG. 6 illustrates the package structure in FIG. 5 when the heat sink plate is adhered to the supporting ring and the chip. Please referring to FIG. 6, the heat sink plate 240 is a rectangular structure. The protruding parts 241 are protruded to four walls of the heat sink plate 240 and correspond to the recesses 231. When the protruding parts 241 are lodged in the recesses 231, the heat sink plate 240 is placed against the inner walls 230b of the supporting ring 230, so that the heat sink plate 240 is not displaced.

Furthermore, the four corners of the supporting ring 230 has enough thickness due to the structure design of the supporting ring 230 along with the heat sink plate 240. As shown in FIG. 6, four L-shaped parts are formed at four corners of the supporting rings 230. The thickness of the L-shaped parts is substantially the same as that of the chip 220, the third thermal adhesive 263 and the heat sink plate 240 enough to prevent the substrate 210 from warping at the corners. Therefore, several tin balls 250 are able to be disposed at the corners of the substrate 210 as I/O pins. The availability rate of the substrate 210 is increased greatly.

Moreover, the chip 220 and the supporting ring 230 are adhered firmly by the first thermal adhesive 261 and the third thermal adhesive 263. Additionally, the first thermal adhesive 261 conducts heat generated by the chip 220 to the heat sink plate 240 and the supporting ring 230, so that heat is dissipated rapidly.

As shown in FIG. 6, preferably the depth D231 of the recesses 231 is substantially the same as the thickness of the protruding parts 241 and the third thermal adhesive 263. As a result, the upper surface 240a of the heat sink plate 240 and the upper surface 230a of the supporting ring 230 are in the same plane.

In the package structure 200 and the heat sink module 300 thereof according to the preferred embodiment of the invention, the heat sink plate 240 and the supporting ring 230 include protruding parts 241 and the recesses 231 respectively. As a result, the heat sink plate 240 is lodged in the supporting ring 230. The corners of the supporting ring 230 have enough thickness to prevent the substrate 210 from warping, so that the tin balls 250 are able to be disposed at the corners of the substrate 210. Furthermore, because the heat sink plate 240 is placed against the inner walls 230b of the supporting ring 230, the supporting ring 230 prevents the heat sink plate 240 from displacing. Therefore, the heat sink module 300 not only dissipates heat of the chip 220 but also prevents the substrate 210 from warping and the heat sink plate 240 from displacing. The efficiency of the manufacturing process and the quality of the package structure 200 are increased greatly.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A package structure comprising:
a substrate;
a chip disposed on the substrate;
a supporting ring disposed on the substrate and surrounding the chip, the supporting ring having at least one recess formed on an upper surface of the supporting ring; and
a heat sink plate disposed on the chip the heat sink having at least one protruding part lodged in the recess.

2. The package structure according to claim 1, wherein the supporting ring have four recesses and the heat sink plate have four protruding parts lodged in the recesses.

3. The package structure according to claim 1, wherein the supporting ring is an annular rectangular structure.

4. The package structure according to claim 3, wherein the recesses are formed on four sides of the supporting ring evenly.

5. The package structure according to claim 1 further comprising:
a first thermal adhesive for adhering the heat sink plate and the chip.

6. The package structure according to claim 5, wherein the supporting ring is made of thermal conductive material.

7. The package structure according to claim 6 further comprising:
a second adhesive for adhering the supporting ring and the substrate; and
a third adhesive for adhering the supporting ring and the heat sink plate.

8. The package structure according to claim 7, wherein the depth of the recesses is substantially the same as the thickness of the protruding part and the third adhesive.

9. The package structure according to claim 1, wherein an upper surface of the heat sink plate and the upper surface of the supporting ring are in the same plane.

10. The package structure according to claim 1 being a flip-chip (FC) package structure.

11. The package structure according to claim 1 being a ball grid array (BGA) package structure.

12. A heat sink module disposed in a package structure, the package structure comprising a substrate and a chip, the chip disposed on the substrate, the heat sink module comprising:
a supporting ring disposed on the substrate and surrounding the chip, the supporting ring having at least one recess formed on an upper surface of the supporting ring; and
a heat sink plate disposed on the chip, the heat sink plate having at least one protruding part lodged in the recesses.

13. The package structure according to claim 12, wherein the supporting ring have four recesses and the heat sink plate have for protruding parts lodged in the recesses.

14. The heat sink module according to claim 12, wherein the supporting ring is an annular rectangular structure.

15. The heat sink module according to claim 14, wherein the recessed are formed on four sides of the supporting ring evenly.

16. The heat sink module according to claim 12, wherein the package structure further comprises:
a first thermal adhesive for adhering the heat sink plate and the chip.

17. The heat sink module according to claim 16, wherein supporting ring is made of thermal conductive material.

18. The heat sink module according to claim 17, wherein the package structure further comprises:
a second adhesive for adhering the supporting ring and the substrate; and
a third adhesive for adhering the supporting ring and the heat sink plate.

19. The heat sink module according to claim 18, wherein the depth of the recesses is substantially the same as the thickness of the protruding parts and the third thermal adhesive.

20. The heat sink module according to claim 12, wherein an upper surface of the heat sink plate and the surface of the supporting ring are in the same plane.
